(19) United States
(12) Patent Application Publication
(10) Pub. No.: US 2017/0339585 A1
(43) Pub. Date: Nov. 23, 2017

(54) TESTING MOBILE DEVICES

(71) Applicant: Google Inc., Mountain View, CA (US)

(72) Inventors: Diana Cortes, San Francisco, CA (US); Jong Hyeop Kim, San Francisco, CA (US); Santosh Guddala, Dublin, CA (US); Terence Kwan, Cupertino, CA (US); Pratyus Patnaik, Los Altos, CA (US); George Patrick Siu, San Francisco, CA (US)

(21) Appl. No.: 15/209,225

(22) Filed: Jul. 13, 2016

Related U.S. Application Data
(60) Provisional application No. 62/338,380, filed on May 18, 2016.

(51) Int. Cl. H04W 24/08; H05K 7/20; H04L 29/08; H04L 12/24; H04L 12/931; H04L 12/26; H05K 9/00; H04W 8/00

(52) U.S. Cl. CPC H04W 24/08; H05K 9/0007; H05K 7/20709; H04W 8/005; H04L 41/0896; H04L 49/40; H04L 43/14; H04L 43/0811; H04L 67/10

(57) ABSTRACT

A data center rack includes a housing, at least one wireless access point (AP) mounted within the housing and wirelessly connectable to a network switch external to the housing, and at least one tray including a plurality of mobile device power connections to provide power to a plurality of mobile devices.

### CROSS-REFERENCE TO RELATED APPLICATIONS

This application claims priority under 35 U.S.C. §119 to pending U.S. Provisional Application Ser. No. 62/338,380, filed May 18, 2016, the entire contents of which are hereby incorporated by reference.

### TECHNICAL FIELD

This disclosure relates generally to wireless network technology.

### BACKGROUND

A cloud based service can be provided to mobile developers to test their mobile applications across a variety of mobile phones. Mobile devices are consumer grade electronics and not meant to be compute nodes. To be scalable and yet economical, a device farm may need to have a high number and density of devices connected per server in a small space. Additionally, a major factor which influences mobile application performance is its ability to optimize for over wide range network conditions and use cases. To simulate different network conditions for application testing on physical devices in data centers, there are a number of inherent challenges with wireless deployments in a small form factor, including Wi-Fi Co-Channel and adjacent channel interferences, interference from external and internal nearby devices, high availability and fault tolerance, unpredictable traffic patterns, isolation of devices and security, and limited human hands help on the data center floor. In some cases, Ethernet (wired) technology offers this functionality as link between a server and clients is dedicated, but wired option is not a viable option for all mobile devices.

### SUMMARY

In a general implementation, a data center rack includes a housing, at least one wireless access point (AP) mounted within the housing and wirelessly connectable to a network switch external to the housing, and at least one tray comprising a plurality of mobile device power connections to provide power to a plurality of mobile devices.

In a first aspect combinable with the general implementation, the housing includes a conductive material.

In a second aspect combinable with the general implementation, the conductive material includes metal.

In a third aspect combinable with the general implementation, the metal includes iron, steel, or aluminum.

In a fourth aspect combinable with the general implementation, the housing includes a plurality of sides, a top, and a bottom.

In a fifth aspect combinable with the general implementation, the plurality of sides includes four sides.

In a sixth aspect combinable with the general implementation, at least some of the plurality of sides include solid panels of a conductive material.

In a seventh aspect combinable with the general implementation, at least some of the plurality of sides include perforated panels of a conductive material.

In an eighth aspect combinable with the general implementation, the perforated panels includes a plurality of perforations sized based at least in part on a wavelength of a radio frequency (RF) signal in an ambient environment external to the housing.

In a ninth aspect combinable with the general implementation, the plurality of perforations are sized based at least in part on a shortest wavelength of a particular RF signal of a plurality of RF signals in an ambient environment external to the housing.

In a tenth aspect combinable with the general implementation, the particular RF signal includes a 5 GHz or a 2.4 GHz signal.

An eleventh aspect combinable with the general implementation, further includes a cooling system configured to cool the plurality of mobile devices during operation of the plurality of mobile devices in a testing operation.

In a twelfth aspect combinable with the general implementation, the cooling system includes a cooling control system and a plurality of cooling modules.

In a thirteen aspect combinable with the general implementation, the plurality of cooling modules include a plurality of fans configured to circulate a cooling airflow through the housing.

In a fourteenth aspect combinable with the general implementation, the plurality of cooling modules include a plurality of heat pipes configured to transfer heat from the plurality of mobile devices to a heat sink external to the housing.

In a fifteenth aspect combinable with the general implementation, the plurality of cooling modules include a plurality of thermosiphons configured to transfer heat from the plurality of mobile devices, through evaporators of the thermosiphons, to condensers of the thermosiphons, to a heat sink external to the housing.

In a sixteenth aspect combinable with the general implementation, the cooling control system includes a plurality of sensors and a controller configured to control the plurality of cooling modules based at least in part on outputs from the plurality of sensors.

In a seventeenth aspect combinable with the general implementation, the plurality of sensors include at least one of a temperature sensor, a humidity sensor, a pressure sensor, a differential pressure sensor, or an enthalpy sensor.

In an eighteenth aspect combinable with the general implementation, the housing includes one or more layers of shielding materials.

In a nineteenth aspect combinable with the general implementation, the housing includes a first layer of shielding material positioned to enclose the access point and the tray, and a second layer of shielding material positioned to enclose the first layer of shielding material.

In a twentieth aspect combinable with the general implementation, the data center rack is configured to determine available mobile devices in the wireless network system; and dynamically enable service set identifiers (SSIDs) based on the determined mobile devices available.

In a twenty-first aspect combinable with the general implementation, the data center rack is configured to dynamically enable or disable one or more of a plurality of antennas to customize a direction of the antennas.

In a twenty-second aspect combinable with the general implementation, the access point is configured to be an OSI layer 2 device.

In a twenty-third aspect combinable with the general implementation, the data center rack is configured to group the at least one wireless access point into federation using network protocols.

In a twenty-fourth aspect combinable with the general implementation, the data center rack is configured to tune power supplied to the at least one wireless access point to a minimum value.

In a twenty-fifth aspect combinable with the general implementation, the data center rack is configured to shut off the at least one tray and the at least one wireless access point in response to an emergency.

In a twenty-sixth aspect combinable with the general implementation, the data center rack is configured to black list traffic to an application running on one of the mobile devices.

A twenty-seventh aspect combinable with the general implementation further includes a network manipulator configured to dynamically allocate bandwidth to the mobile devices.

In a twenty-eighth aspect combinable with the general implementation, the data center rack is configured to activate at least one standby access point in response to determining that a mobile device is losing an access point.

In a twenty-ninth aspect combinable with the general implementation, the data center rack is configured to measure a temperature inside the housing and adjust the temperature based on the measured temperature to maintain a predetermined number of mobile devices available in the housing.

In a thirtieth aspect combinable with the general implementation, the data center rack is configured to monitor RF interference and channel attenuation and, based on parameters received by sensors and monitoring data from the mobile devices, determine one or more radio settings of the access point.

A thirty-first aspect combinable with the general implementation further includes a server configured to communicate with one of the mobile devices through the wireless access point.

A thirty-second aspect combinable with the general implementation further includes a wireless network analyzer configured to analyze a status of the wireless network connectivity of one or more mobile devices.

A thirty-third aspect combinable with the general implementation further includes a monitoring server and a network manipulator, and the wireless network analyzer is coupled to the monitoring server and the network manipulator.

In a thirty-fourth aspect combinable with the general implementation, the housing includes at least one door sensor configured to detect an open/close event of a door of the rack.

In another general implementation, a method includes providing power to a plurality of mobile devices connected to a plurality of power connections in at least one tray of a data center rack of the data center; activating at least one wireless access point (AP) mounted within a housing of the rack to wirelessly connect to a network switch of the data center that is external to the housing; and monitoring wireless network connectivity of one of the mobile devices when an application is running on the one of the mobile devices that is wirelessly connected to the at least one wireless access point.

A first aspect combinable with the general implementation further includes determining available mobile devices in a wireless network system including the at least one wireless access point and dynamically enabling service set identifiers (SSIDs) based on the determined available mobile devices.

A second aspect combinable with the general implementation further includes dynamically enabling or disabling one or more of a plurality of antennas of the mobile devices to customize a direction of the antennas.

A third aspect combinable with the general implementation further includes grouping the at least one wireless access point into federation using network protocols.

A fourth aspect combinable with the general implementation further includes tuning power supplied to the at least one wireless access point to a minimum value.

A fifth aspect combinable with the general implementation further includes shutting off the at least one tray and the at least one wireless access point in response to an emergency.

A sixth aspect combinable with the general implementation further includes black-listing traffic to the application running on the one of the mobile devices.

A seventh aspect combinable with the general implementation further includes, in response to a determination of the one of the mobile devices losing the at least one wireless access point, activating at least one standby access point.

An eighth aspect combinable with the general implementation further includes monitoring radio-frequency (RF) interference between the mobile devices; and based on the monitoring data from the mobile devices, adjusting one or more radio settings of the at least one wireless access point.

In another general implementation, a data center includes a plurality of network switches and a plurality of distributed data center racks. Each data center rack includes a housing, at least one wireless access point (AP) mounted within the housing and wirelessly connectable to a network switch of the plurality of network switches external to the housing, and a plurality of trays, each tray including a plurality of mobile device power connections to provide power to a plurality of mobile devices.

These general and specific aspects may be implemented using a device, system, method, or any combinations of devices, systems, or methods. The details of one or more implementations are set forth in the accompanying drawings and the description below. Other features, objects, and advantages will be apparent from the description and drawings, and from the claims.

### BRIEF DESCRIPTION OF THE DRAWINGS

FIG. 1A is a block diagram of an example data center having multiple racks.

FIG. 1B is a block diagram of example racks.

FIG. 2A is a block diagram of an example data center rack.

FIG. 2B is a block diagram of an example data center.

FIG. 3A shows an example door with apertures for enclosing a rack.

FIG. 3B shows an example placement of fans inside of a rack door.

FIG. 3C shows example fans placements aligned with device trays in a rack.

FIG. 4 depicts an example process of testing mobile devices in a data center according to the present disclosure.

### DETAILED DESCRIPTION

For providing a cloud based service to mobile developers to test their mobile applications across a variety of mobile phones, a stable, economical and scalable device farm is preferable. To be scalable and yet economical, one may need to have a high number and density of devices connected per server in a small space. The present disclosure describes systems, methods, and apparatus for testing mobile devices and managing a wireless network in a data center, including scaling mobile device rack and infrastructure in a stable operating environment. The data center can be a cloud test lab (CTL) or a server center for a wireless network. The technology can be also applied to any other devices besides mobile devices.

In some implementations, a number of data center racks are distributed in the data center. Each data center rack includes a housing, at least one wireless access point (AP) mounted within the housing and wirelessly connectable to a network switch external to the housing, and a plurality of trays, each tray including a plurality of mobile device power connections to provide power to a plurality of mobile devices. In such a way, the data center rack (or the mobile device rack) and associated infrastructure can be scaled.

One of the primary ways to ensure device stability is by ensuring consistent wireless network connectivity of the devices. Various implementations of ensuring consistent wireless network connectivity of the devices are disclosed.

In some implementations, due to RFI (Radio frequency interference) and limitations in the current wireless 2.4 GHz and 5 GHz wireless technology, RF shielding materials are used to isolate RF from the mobile devices within the data center rack. In some examples, the data center rack is custom built and made of steel, iron, aluminum or any other solid conductive metal. Selection of the metal used can depend on conditions of the data center rack architecture for cooling.

In some implementations, perforations and openings for cables on the data center rack are built to custom configure based on temperature conditions and needed attenuation inside the rack. Sizes of the perforations can be determined by a wavelength of the smallest frequency speed of Light (m/s)/Frequency(cycles/s)=Wavelength(m/s).

In some implementations, the data center rack is modular and customizable for economically deployment. For example, if a data center cooling solution airflow is bottom up, perforation panels can be installed in a bottom of the rack and air leaves from a top of the rack. In some examples, multiple temperature, humidity sensors are installed in the rack and report statistics periodically for abnormalities. The data center rack can be configured such that in an event of emergency such as a fire hazard, the rack and all wireless equipment can be automatically shut off.

In some implementations, the temperature inside the shielded racks is measured, fan speed is adjusted, and a status of the rack is communicated to a test manager. The status of the rack also includes battery health and battery temperature statistics. A test manager application can determine, e.g., automatically, an ability to perform test on devices based on this data. In order to maintain a required number of available devices, temperature inside the racks needs to be controlled programmatically.

In some implementation, dedicated service set identifiers (SSIDs) are dynamically allocated with a Wi-Fi spectrum profile for each type of devices. For example, some phones can only connect to 36, 40, 44, or 48 “channels”. To solve this issue, the SSIDs that are broadcasted can be dynamically enabled based on devices available in racks.

In some implementations, RF interference and channel attenuation are continuously monitored. Based on parameters received by sensors and monitoring data from devices, access point (AP) radio settings are programmatically determined and applied, such that the signal coverage is changed based on a layout of the rack. In some examples, a higher power level of wireless signal makes the signal coverage elliptical, and a lower signal level of wireless signal makes the signal coverage circular.

In some examples, a configuration and device layout is changed based on device form factors and the rack layout is determined by temperature conditions in the rack. Also 2.4 GHz Wi-Fi channels that have a lowest frequency used spread more than 5 GHz Wi-Fi channels, so power levels are tuned down for 2.4 GHz Wi-Fi channels and tuned up for 5 GHz Wi-Fi channels to achieve identical speeds. In some examples, the access point's radio settings are programmatically controlled based on interference and channel data using external network and internal network signal to noise ratio (SNR) data.

In some implementations, a device primarily relies on wireless for data. If the device loses an access point, it can trigger device availability ratios for an overall devices tested in a data center. The status of wireless devices can be determined by Simple Network Management Protocol (SNMP) data and commands to enable the secondary wireless access point can be sent using automation tools. Standby access points can be activated when a fault is detected.

In some implementations, a network manipulator is used to dynamically allocate bandwidth to the mobile devices in the rack. In some examples, the network manipulator includes a dynamic router module installed on a gateway which allocates needed bandwidth for a test scenario. Transmitted (TX) and received (RX) packets from the devices can be shaped by a tool, e.g., IPTABLES can be used as a underlying tool to shape the TX, RX packets from the devices.

In some cases, ability for an operator to blacklist traffic to an application is implemented by interfacing test service with access point management layer. In some cases, ability to customize a radio antenna direction remotely using tools can be implemented by pre-installing multiple antennas in the racks and dynamically disabling/enabling any one of the multiple antennas. In some cases, when a device is not in use, Wi-Fi functionality of the device can be turned off to reduce load on APs.

In some implementations, in order to scale wireless AP and wireless communications/air interface stabilities, the data center rack is configured to use wireless AP as open systems interconnection (OSI) Layer 2 device. With this, a wireless AP operates like a radio antenna bridged to a wire network, which means that the data center rack has a control Layer 3 on mobile devices including manipulating gateways/egress endpoints.

In some examples, the data center rack uses network protocols to group all APs into federation, including using spanning tree protocol to detect cycles in network environments, configuring Bridge Protocol Data Unit (BPDU) frame data to be allowed on upstream switches, and/or making one of wireless APs in the group become a master AP which loads balance air traffics across the group of APs or a cluster of APs.

The data center rack can also federate wireless APs into one group, e.g., meshing or clustering APs, which provides the following benefits: I) co-channel interferences can be minimized and even can be eliminated by tuning up a cluster's channel and dynamic channel selection if location is fixed; II) with using a Dynamic Host Configuration Protocol (DHCP) server, egress traffics can be spread/fan out into multiple upstream switches and providers by providing specified network gateways through the DHCP server.

To scale beyond a wireless AP cluster with limited spaces such as inside of a server rack (or the data center rack) and create stable multiple wireless AP clusters within limited spaces, wireless AP power can be tuned up to be minimum. Minimizing wireless AP power can reduce co-channel interferences because as the power is increased the wireless AP can create co-channel interference with different AP cluster groups. In a particular example, only 12.5% or 25% of full transmit power is used.

In some implementations, depending on product/OEM, a single wireless AP cluster can include any number of APs. The number of APs in the AP cluster can depend on wireless AP controller's specifications and how much AP controller/master can take traffics (e.g., specially BPDU information). In some examples, meshing/clustering APs mechanism relies on network OSI layer 2, so it can technically mesh a max total network capacity on L2. In some examples, a wireless AP cluster is formed from 2 APs to over 1,000 APs. In a particular example, one wireless AP cluster includes from 16 APs to 32_APs.

These general and specific aspects may be implemented using a device, system, method, or any combinations of devices, systems, or methods. The details of one or more embodiments of the subject matter described in this specification are set forth in the accompanying drawings and the description below. Other features, aspects, and advantages of the subject matter will become apparent from the description, the drawings, and the claims.

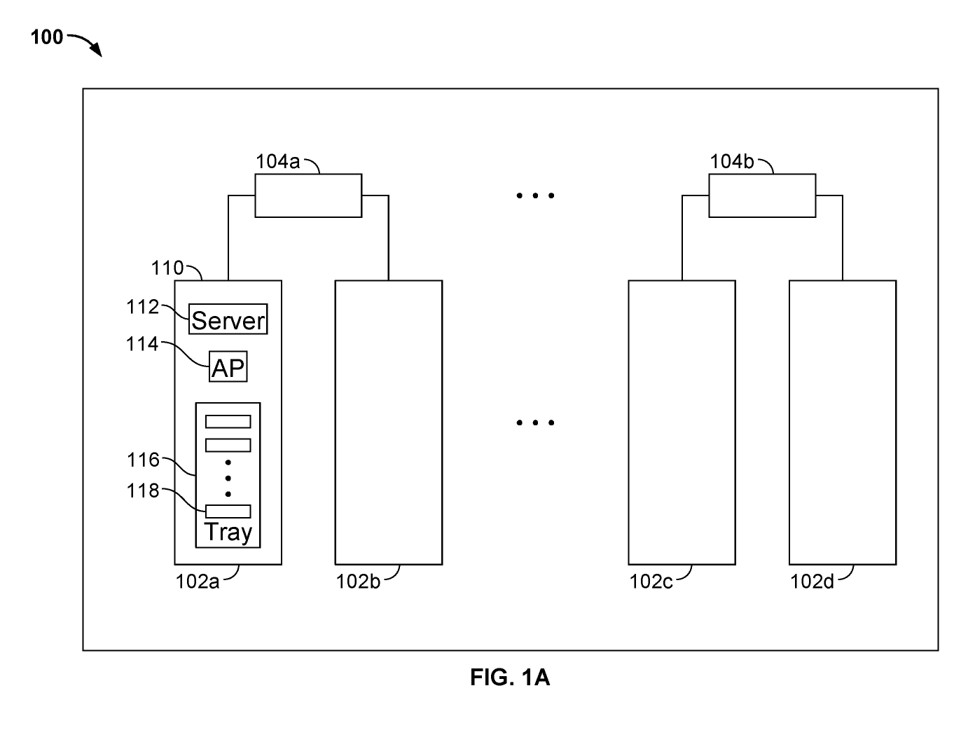

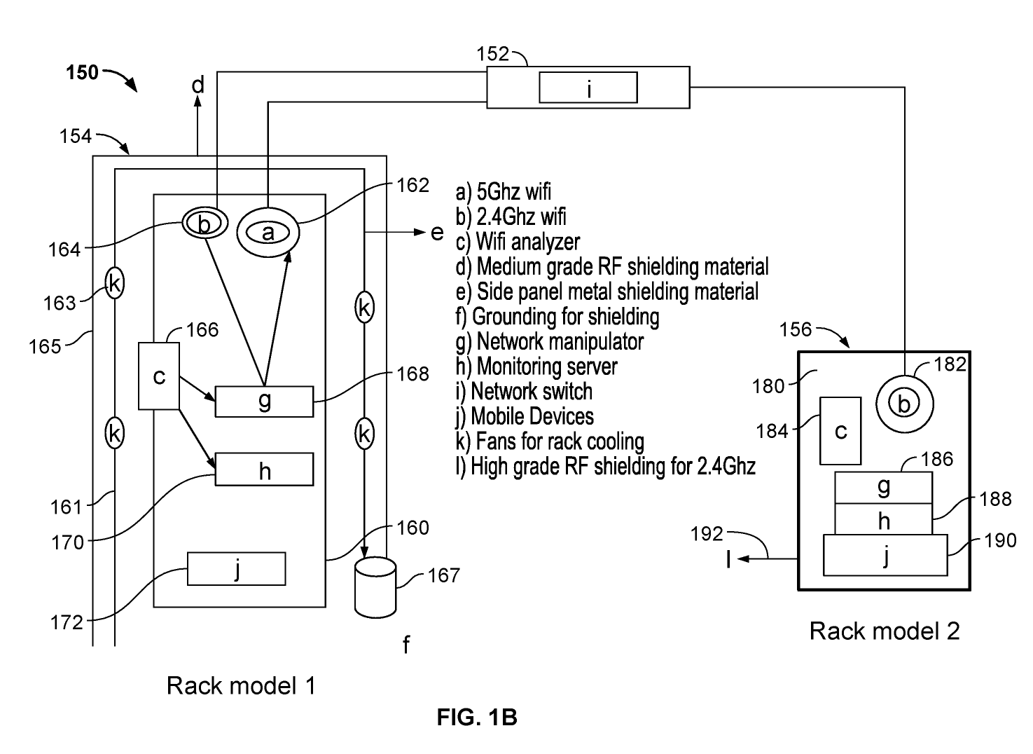

FIG. 1A shows a schematic diagram of an example data center 100 (or a server room or a cloud test lab). The data center 100 includes a plurality of data center racks 102a, 102b, 102c, 102d and a plurality of network switches 104a, 104b. Each data center rack, e.g., rack 102a, includes a housing 110, at least one server 112, at least one wireless access point (AP) 114 mounted within the housing 110 and wirelessly connectable to the network switch 104a external to the housing 110, and a plurality of trays 116. Each tray 116 can include a plurality of mobile device power connections 118 to provide power to a plurality of mobile devices (not shown). The mobile device power connections can include USB hubs and/or power supply plugs. A mobile device can communicate with the server 112 through the access point 114 via wireless communication.

In some implementations, the housing 110 includes a conductive material. The conductive material can be metal, e.g., iron, steel, or aluminum. The housing 110 can include a plurality of sides (e.g., four sides), a top, and a bottom. In some examples, at least some of the plurality of sides include solid panels of the conductive material.

In some implementations, the housing 110 includes a shielding material configured to shield off a Wi-Fi signal with a certain frequency, e.g., 2.4 GHz or 5 GHz. The housing 110 can include one or more layers of shielding materials. The layers of shielding materials are grounded. In some examples, the housing 110 has a first layer of shielding material positioned to enclose the access points and the trays, and a second layer of shielding material positioned to enclose the first layer of shielding material.

In some implementations, at least some of the plurality of sides include perforated panels of the conductive material. The perforated panels can include a plurality of perforations sized based at least in part on a wavelength of a radio frequency (RF) signal in an ambient environment external to the housing. For example, the plurality of perforations are sized based at least in part on a shortest wavelength of a particular RF signal of a plurality of RF signals in an ambient environment external to the housing. In some examples, the particular RF signal comprises a 5 GHz or a 2.4 GHz signal.

In some implementations, as discussed in further details below, the data center rack includes a cooling system configured to cool the plurality of mobile devices during operation of the plurality of mobile devices in a testing operation. The cooling system can include a cooling control system and a plurality of cooling modules. In some examples, the plurality of cooling modules include a plurality of fans configured to circulate a cooling airflow through the housing. In some examples, the plurality of cooling modules include a plurality of heat pipes configured to transfer heat from the plurality of mobile devices to a heat sink external to the housing. In some examples, the plurality of cooling modules includes a plurality of thermosiphons configured to transfer heat from the plurality of mobile devices, through evaporators of the thermosiphons, to condensers of the thermosiphons, to a heat sink external to the housing. In some examples, the cooling control system includes a plurality of sensors and a controller configured to control the plurality of cooling modules based at least in part on outputs from the plurality of sensors. The plurality of sensors includes at least one of a temperature sensor, a humidity sensor, a pressure sensor, a differential pressure sensor, or an enthalpy sensor.

In some implementations, the housing includes door sensors for racks trigger open/close events, and the events can be used to determine current and periodical change in rack. The door sensors information can be also used for auditing the devices maintenance, physical security alerts and possible wireless interference spikes.

FIG. 1B shows a schematic diagram of example racks 154 and 156. The data center rack 102a, 102b, 102c, or 102d of FIG. 1A can be one of the racks 154 and 156. Rack 154 or 156 is coupled to a network switch 152, e.g., the network switch 104a or 104b of FIG. 1A. Rack 154 includes a housing 160, which can be shielded from external environment with external protector 161, e.g., having side panel metal shielding material, and/or external protector 165, e.g., having medium grade RF shielding material. The protector 165 can enclose the external protector 161 which is positioned closer to the housing 160. A number of fans 163 for rack cooling can be distributed on the protector 161. The external protectors 161 and 165 are both coupled to the ground 167 for shielding.

Rack 154 includes a 5 GHz Wi-Fi AP 162, a 2.4 GHz Wi-Fi AP 164, a Wi-Fi analyzer 166, a network manipulator 168, and a monitoring server 170. A number of mobile devices 172 are positioned within the housing 160 of Rack 154. The network manipulator 168 is configured to dynamically allocate bandwidth to the mobile devices 172 in Rack 154. In some examples, the network manipulator 168 includes a dynamic router module installed on a gateway which allocates needed bandwidth for a test scenario. The network manipulator 168 is coupled to both 5 GHz Wi-Fi AP 162 and 2.4 GHz Wi-Fi AP 164. The monitoring server 170 can be similar to the server 112 of FIG. 1A, and is configured to monitor Wi-Fi connectivity of the mobile devices 172. The Wi-Fi analyzer 166 is configured to collect data from the network manipulator 168 and the monitoring server 170 and transmit the data, e.g., to a test manager application, for processing.

Rack 156 includes a housing 180, a 2.4 GHz Wi-Fi AP 182, a Wi-Fi analyzer 184, a network manipulator 186, a monitoring server 188, and a plurality of mobile devices 190. The 2.4 GHz Wi-Fi AP 182, the Wi-Fi analyzer 184, the network manipulator 186, and the monitoring server 188 can be similar to 2.4 GHz Wi-Fi AP 164, the Wi-Fi analyzer 166, the network manipulator 168, and the monitoring server 170, respectively. Different from Rack 154, Rack 156 includes a protector 192 which has a high grade RF shielding material for shielding 2.4 GHz Wi-Fi RF.

### Example Implementations

A data center, e.g., a cloud test lab, relies on wireless radio frequency (RF) for device connectivity. Wireless Radio frequencies standardly used on phones operates on two frequencies 2.4 GHz and 5 GHz. Under the Federal Communications Commission (FCC) regulatory domain, the 5 GHz frequency (UNII-1, UNII-2, UNII-2-Extended, UNII-3) has ˜22 20-MHz non-overlapping channels available. Under European Telecommunications Standards Institute (ETSI), there are 19 channels available, while in Asia-Pacific (APAC) region, there are 13 channels available. Note that channel availability can also vary per Wi-Fi device and/or Access Point. For example, in China using an Aruba AP-135 access point, the channels available are only 5: 149, 153, 157, 161, 165. The 2.4 GHz frequency has only 3 22-MHz non-overlapping channels (1, 6, 11). 5-GHz-capable phones have better success rate than 2.4 GHz as it offers bigger spectrum.

Due to RF interference (co-channel and adjacent channel interference) devices may be unable to finish tests or fall to “unhealthy” status (to send/receive data). Although there could be other possibilities that device become “unhealthy,” Radio Frequency interference (RFI) may be a big causing factor. RFIs originate from external wireless access points and clients of which the CTL has no control, as well as internal RFI, which the CTL can manage. RFI can also affect functionality of other hardware in the racks, e.g., USB hubs or USB cables which is the primary means to connect to devices and a debug bridge, e.g., ADB (Android Debug Bridge), on mobile devices.

Due to limitations of 2.4 GHz and 5 GHz radio frequencies, a viable option is to shield the Radio Frequency. In some cases, RF shielding material is draped around the racks for controlling radiated radio frequency interference but it may be not effective for initial testing.

In a particular example, racks in a CTL are configured to have enough RF capacity to run tests on 10,000 devices, reliably connect to Wi-Fi and achieve a desirable data rate 10 Mbits/sec per device. 99% attenuation (or zero wireless exposure) of external 2.4 GHz and 5 GHz signals from inside of the racks can be achievable. Materials for device trays are identified to facilitate Wi-Fi propagation. The racks also adhere to safety and power requirements. Placements of wireless access points and/or external antennas are also determined. Also the racks are configured to have sufficient number of “U”s to mount servers and devices. For example, finalization of server hardware can help decide how many “U”s are required and redesign the arrangement of the servers to allow RF signal to propagate.

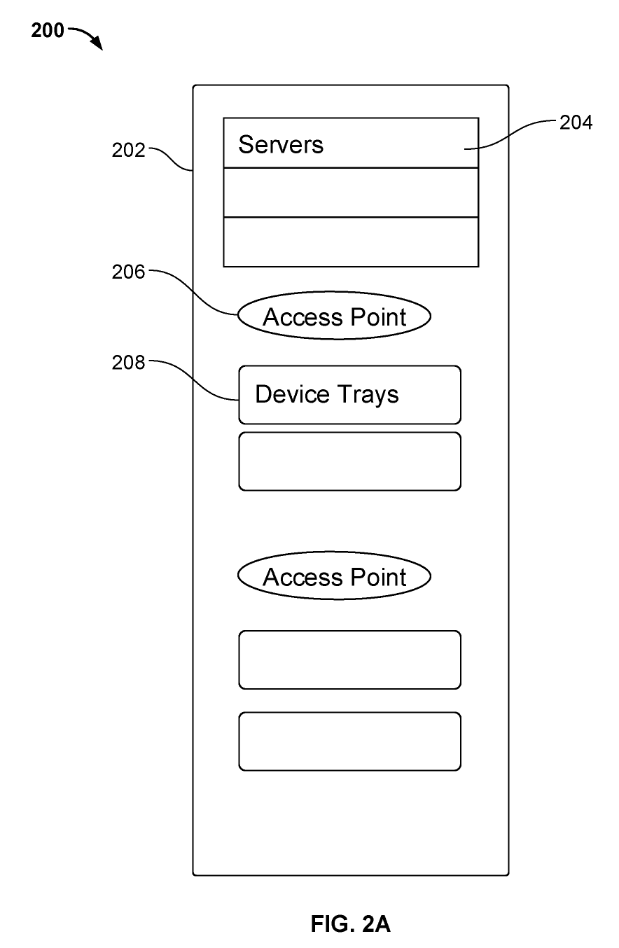

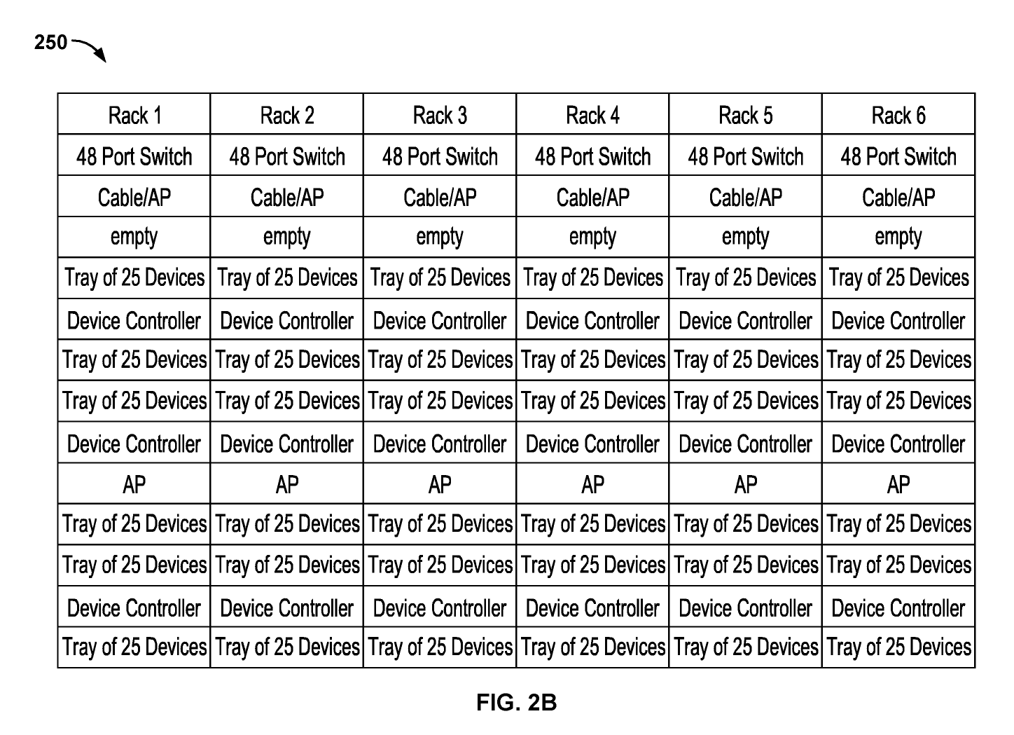

FIG. 2A shows an example rack 200 for the CTL. The rack 200 can be similar to rack 102a of FIG. 1A, rack 154 or 156 of FIG. 1B. The rack 200 includes a housing 202 enclosing one or more servers 204, one or more access points 206, and one or more device trays 208. The rack 200 is grounded. The internal device trays 208 can be built with fiberglass, plastic or other reflective material for RF propagation.

FIG. 2B shows an example data center 250 including multiple racks, e.g., from rack 1 to rack 6. Each rack includes 1 cable or AP and one extra AP, 6 trays of devices each holding 25 devices, 2 device controllers, and 48 port switches. All the racks are grounded. The data center 250 can be scaled up by adding more racks. The number of APs can be determined based on the number of devices.

As RF cannot penetrate through metals, and high conductive metal absorbs the RF, racks can be made of steel, iron, aluminum or any solid conductive metal. Racks can be closed from sides, top and bottom metal. Racks are also grounded. Generally, no painting is on the racks as paint is non-conductive material.

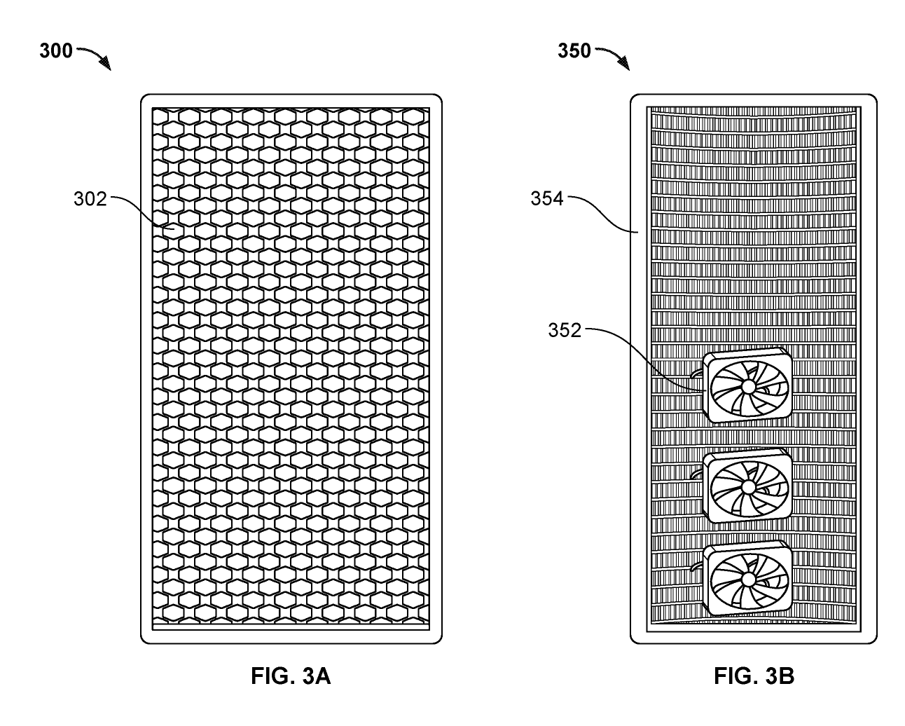

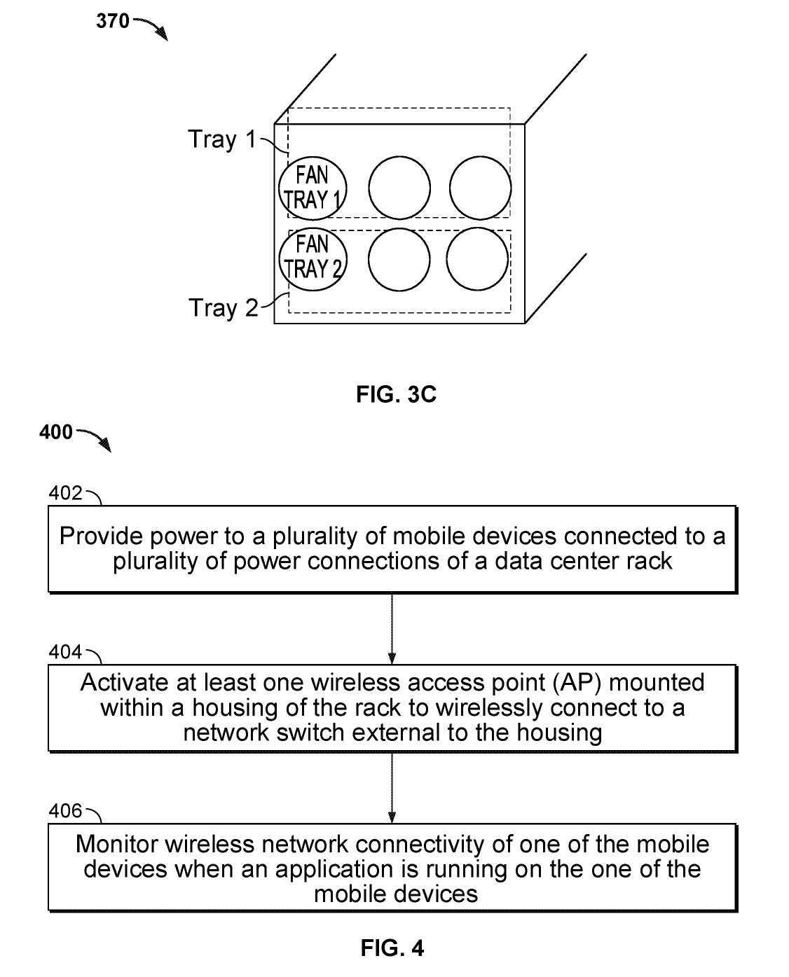

In some implementations, apertures, perforations, holes and/or openings for cables on the data center rack are built. FIG. 3A shows an example door 300 with apertures/holes 302 for enclosing a rack. The door can be used as a front, back, top, or bottom door of the rack.

As RF can penetrate through apertures, penetrations and/or seams in the enclosure, the performance of a rack enclosure depends on the size of apertures and how the seams and apertures are treated. For example, the size of the apertures, perforations, or openings can be smaller than the size of smallest wavelength (or the wavelength of the highest frequency). The wavelength is calculated by:

Speed of Light (m/s)/Frequency (cycles/s)=Wavelength (m/s).

For 2.4 GHz frequency, the maximum size of aperture/perforation/opening should be no more than ˜12.5 cm. For the 5 GHz frequency, the maximum size of the aperture should be no more than ˜5.56 cm. In some examples, rack front and/back door holes for air circulation is below 5.56 cm wavelength, particularly no more than 4 mm by 4 mm in size.

In some cases, holes are honeycomb-shaped or round. A thickness of metal sheets for doors, e.g., the door 300, may be no less than 4 mm for shielding. For other openings such cable manager needs to be shielded at ends with good conductive material like Fabric-Over-Foam EMI gaskets

A rack may need sufficient cooling from different locations for devices. In some implementations, a trade-off is made to allow air to flow in and out of a rack enclosures for avoiding heating issues inside the rack while still blocking unwanted RF interference. FIG. 3B shows placements 350 of fans 352 inside of a door 354 of the rack. In some examples, if the data center cooling solution airflow is bottom up, the perforation panels are installed in bottom of the rack and air leave from top of the rack. As FIG. 3C illustrates, device trays (e.g., tray 1, tray 2) in the rack can be aligned with fans placements (e.g., fan tray 1, fan tray 2).

FIG. 4 depicts an example process 400 of testing mobile devices in a data center according to the present disclosure. The data center can be similar to the data center 100 of FIG. 1A, the data center 150 of FIG. 1B, or the data center 250 of FIG. 2B. In some implementations, the data center includes a plurality of distributed data center racks and a plurality of network switches external to the data center racks. Each data center rack can be similar to the rack 104a or 104b of FIG. 1A, the rack 154 or 156 of FIG. 1B, the rack 200 of FIG. 2A, the racks of FIG. 2B.

A data center rack provides power to a plurality of mobile devices connected to a plurality of power connections in at least one tray of the rack (402). The data center rack can include a housing and a plurality of trays. Each tray has a plurality of power connections to provide power to a plurality of mobile devices.

At least one wireless access point (AP) in the rack is activated to wirelessly connect to a network switch of the data center (404). The at least one wireless access point is mounted in the housing, while the network switch is external to the housing of the rack. The network switch is coupled to wireless APs in one or more different racks. The network switch can be further coupled to a server of the data center.

In some implementations, the mobile devices and the wireless AP form a wireless network system. One or more of the powered mobile devices connected to the tray of the rack can communicate through the wireless AP, e.g., to the server of the data center.

Wireless network connectivity of one of the mobile devices is monitored when an application is running on the one of the mobile devices (406). The mobile device is wirelessly connected to the activated wireless AP. Based on the monitored data of the wireless network connectivity, a running performance of the application can be determined.

In some implementations, the data center rack is operable to monitor wireless network connectivity of the mobile devices in the rack, determine available mobile devise in the wireless network system including the at least wireless AP, and dynamically enable service set identifiers (SSIDs) based on the determined available mobile devices. The data center rack can be also configured to measure a temperature inside the housing and adjust the temperature based on the measured temperature to maintain a predetermined number of mobile devices available in the housing.

In some implementations, the data center rack is configured to group the at least one wireless access point into federation using network protocols. The data center rack can also tune power supplied to the at least one wireless access point to a minimum value. In some cases, in response to a determination of a mobile device losing a wireless access point, the data center rack can activate at least one standby access point.

In some implementations, the data center rack dynamically enables or disables one or more of a plurality of antennas of the mobile devices to customize a direction of the antennas. The data center rack can also shut off one of the trays and the at least one wireless access point in response to an emergency. The data center rack can also black list traffic to an application running on a mobile device.

The data center rack can be configured to monitor radio-frequency (RF) interference between the mobile devices and/or channel attenuations for the mobile devices. Based on the monitoring data from the mobile devices and/or parameters received by sensors, the data center rack can adjust one or more radio settings of the at least one wireless access point.

While this specification contains many specific implementation details, these should not be construed as limitations on the scope of what may be claimed, but rather as descriptions of features specific to particular embodiments. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. Other embodiments are within the scope of the following claims.

What is claimed is:

1. A data center rack, comprising:
a housing;
at least one wireless access point (AP) mounted within the housing and wirelessly connectable to a network switch external to the housing; and
at least one tray comprising a plurality of mobile device power connections to provide power to a plurality of mobile devices.

2. The data center rack of claim 1, wherein the housing comprises a plurality of sides, and wherein at least some of the plurality of sides comprise perforated panels of a conductive material.

3. The data center rack of claim 2, wherein the perforated panels comprise a plurality of perforations sized based at least in part on a wavelength of a radio frequency (RF) signal in an ambient environment external to the housing.

4. The data center rack of claim 3, wherein the plurality of perforations are sized based at least in part on a shortest wavelength of a particular RF signal of a plurality of RF signals in an ambient environment external to the housing.

5. The data center rack of claim 1, further comprising a cooling system configured to cool the plurality of mobile devices during operation of the plurality of mobile devices in a testing operation.

6. The data center rack of claim 1, wherein the housing comprises at least one door sensor operable to detect an open/close event of a door of the rack.

7. The data center rack of claim 1, wherein the housing comprises a first layer of shielding material positioned to enclose the access point and the tray, and
a second layer of shielding material positioned to enclose the first layer of shielding material.

8. The data center rack of claim 1, further comprising a network manipulator operable to dynamically allocate bandwidth to the mobile devices.

9. The data center rack of claim 1, further comprising a server operable to communicate with one of the mobile devices through the wireless access point.

10. The data center rack of claim 1, further comprising a wireless network analyzer operable to analyze a status of wireless network connectivity of one or more mobile devices.

11. A method of testing mobile devices in a data center, comprising:
providing power to a plurality of mobile devices connected to a plurality of power connections in at least one tray of a data center rack of the data center;
activating at least one wireless access point (AP) mounted within a housing of the rack to wirelessly connect to a network switch of the data center that is external to the housing; and
monitoring wireless network connectivity of one of the mobile devices when an application is running on the one of the mobile devices that is wirelessly connected to the at least one wireless access point.

12. The method of claim 11, further comprising:
determining available mobile devices in a wireless network system including the at least one wireless access point; and
dynamically enabling service set identifiers (SSIDs) based on the determined available mobile devices.

13. The method of claim 11, further comprising:
dynamically enabling or disabling one or more of a plurality of antennas of the mobile devices to customize a direction of the antennas.

14. The method of claim 11, further comprising:
grouping the at least one wireless access point into federation using network protocols.

15. The method of claim 11, further comprising:
tuning power supplied to the at least one wireless access point to a minimum value.

16. The method of claim 11, further comprising:
shutting off the at least one tray and the at least one wireless access point in response to an emergency.

17. The method of claim 11, further comprising:
black-listing traffic to the application running on the one of the mobile devices.

18. The method of claim 11, further comprising:
in response to a determination of the one of the mobile devices losing the at least one wireless access point, activating at least one standby access point.

19. The method of claim 11, further comprising:
monitoring radio-frequency (RF) interference between the mobile devices; and
based on the monitoring data from the mobile devices, adjusting one or more radio settings of the at least one wireless access point.

20. A data center comprising:
a plurality of network switches; and
a plurality of distributed data center racks, each data center racks comprising:
a housing;
at least one wireless access point (AP) mounted within the housing and wirelessly connectable to a network switch of the plurality of network switches external to the housing; and
a plurality of trays, each tray comprising a plurality of mobile device power connections to provide power to a plurality of mobile devices.
